(19) United States
(12) Patent Application Publication
(10) Pub. No.: US 2011/0220947 A1
(43) Pub. Date: Sep. 15, 2011

(54) LIGHT EMITTING DIODE UNIT

(75) Inventor: WEI-MING PAI, Tainan City (TW)

(73) Assignee: GIO Optoelectronics Corp., Tainan City (TW)

(21) Appl. No.: 13/046,688

(22) Filed: Mar. 11, 2011

(30) Foreign Application Priority Data
Mar. 12, 2010 (TW) 099107201
Jul. 6, 2010 (TW) 099122119

(51) Int. Cl. H01L 33/60

(52) U.S. Cl. 257/98; 257/E33.072

(57) ABSTRACT

A light emitting diode (LED) unit includes a carrier, a plurality of LED dies, a reflecting element and a molding material. A length-width ratio of the carrier is greater than or equal to 5. The LED dies are disposed on the carrier along a longitudinal direction of the carrier. The reflecting element has two reflecting portions disposed on the carrier along the longitudinal direction. The LED dies are disposed between the reflecting portions. The molding material covers the LED dies and contacts with the reflecting element.

### CROSS REFERENCE TO RELATED APPLICATIONS

This Non-provisional application claims priority under 35 U.S.C. §119(a) on Patent Application No(s). 099107201 filed in Taiwan, Republic of China on Mar. 12, 2010, and 099122119 filed in Taiwan, Republic of China on Jul. 6, 2010, the entire contents of which are hereby incorporated by reference.

### BACKGROUND OF THE INVENTION

1. Field of Invention

The invention relates to a light emitting unit and, in particular, to a light emitting diode (LED) unit.

2. Related Art

A light emitting diode (LED) is a new light emitting source having the advantages of the long lifetime, the small size and the advantage that it cannot be easily broken. The LED is also applied to many products, such as an illuminating apparatus, a backlight module of a flat panel display and the like.

Referring to FIG. 1, a conventional LED unit 3 includes a substrate 31, a plurality of LED dies 32 and a plurality of molding materials 33. The LED dies 32 are disposed on the substrate 31, and the molding materials 33 respectively cover the LED dies 32. Each molding material 33 cover the corresponding LED die 32 by way of dispensing, and the molding material 33 is doped with fluorescent particles. In the dispensing process, however, the fluorescent particles, which are originally suspended in the molding material, may be gradually deposited, and the ratio of the deposited fluorescent particles is not always constant in each dispensing process. So, the concentration of the fluorescent particles corresponding to each LED die 32 is not fixed, and the overall LED unit 3 may have uneven luminance.

Thus, it is an important subject of the invention to provide a LED unit, such that the fluorescent particles corresponding to each LED die may become uniform, and the uniform luminance can be obtained.

### SUMMARY OF THE INVENTION

In view of the foregoing, an object of the invention to provide a light emitting diode (LED) unit, so that fluorescent particles corresponding to LED dies can be uniform and the uniform luminance can be thus obtained.

To achieve above object, the invention discloses a light emitting diode (LED) unit including a carrier, a plurality of LED dies, a reflecting element and a molding material. The carrier has a length-width ratio greater than or equal to 5. The LED dies are disposed on the carrier along a longitudinal direction of the carrier. The reflecting element has two reflecting portions disposed on the carrier along the longitudinal direction. The LED dies are disposed between the reflecting portions. The molding material covers the LED dies and contacts with the reflecting element.

As mentioned hereinabove, the same molding material covers a plurality of LED dies in the LED unit of the invention, so that the molding material corresponding to each LED die has the substantially constant thickness. The molding material contains the mixed fluorescent particles, and the concentration of the fluorescent particles corresponding to each LED die is also substantially constant, so that the uniform luminance can be obtained. In addition, the LED dies of the invention are disposed along the longitudinal direction of the carrier, and reflecting elements, for reflecting the light outputted from the LED die, are disposed on two sides of the LED die, so that the higher light availability is obtained.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic illustration showing a conventional LED unit;

FIG. 2 is a schematic illustration showing a LED unit according to a preferred embodiment of the invention;

FIG. 3 is a schematic illustration showing an aspect of the LED unit of FIG. 2, wherein a reflecting element and a carrier are concave-convex matched;

FIGS. 4 and 5 are schematic illustrations showing LED unit according to other aspects of FIG. 2, wherein reflecting elements are closed;

FIGS. 6 and 7 are schematic illustrations showing LED units according to other aspects of FIG. 2, wherein each LED unit further includes a supporting portion;

FIG. 8 is a schematic illustration showing a LED unit according to another aspect of FIG. 2, wherein the LED unit further includes spacers; and

FIG. 9 is a schematic illustration showing a LED unit according to still another aspect of FIG. 2, wherein the carrier is a lead frame.

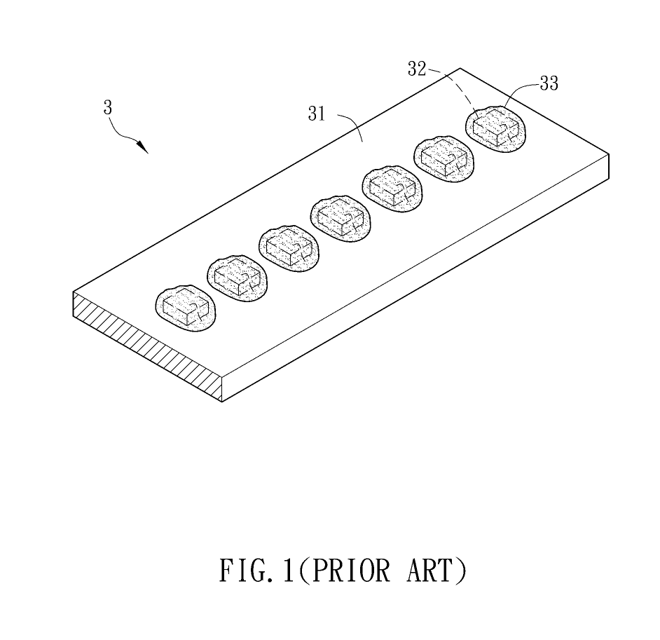

### DETAILED DESCRIPTION OF THE INVENTION

The present invention will be apparent from the following detailed description, which proceeds with reference to the accompanying drawings, wherein the same references relate to the same elements.

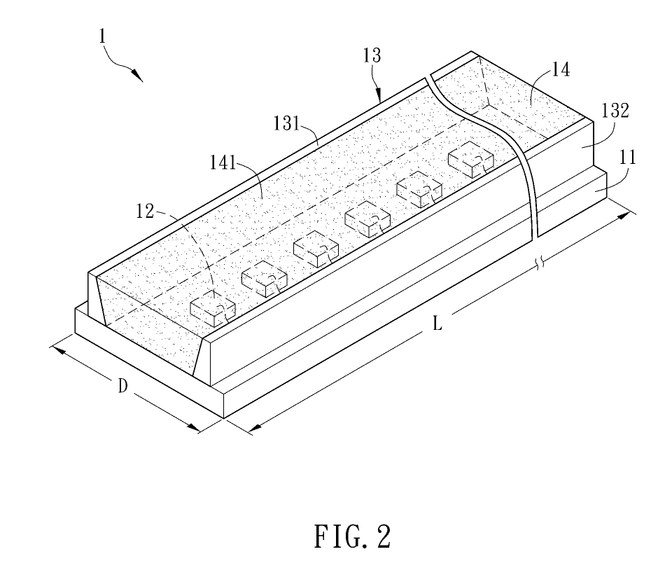

Referring to FIG. 2, a light emitting diode (LED) unit 1 according to a preferred embodiment of the invention includes a carrier 11, a plurality of LED dies 12, a reflecting element 13 and a molding material 14. The LED unit 1 may be a light bar, and may be applied to the fields, such as an illumination device, a lightbox, a backlight module or a display device, wherein the display device includes a flat panel display or an outdoor advertising space.

The carrier 11 is longitudinal and has a length-width ratio greater than or equal to 5. That is, a length L of the carrier 11 is greater than or equal to five times of a width D of the carrier 11. The carrier 11 may be, for example, a substrate or a lead frame, wherein the substrate may be, for example, a circuit board made of materials, which may include the metal, resin, ceramic, glass or plastic material. The substrate may be, for example, a metal core circuit board, a resin circuit board, a ceramic circuit board or a metal (aluminum or copper) circuit board. Herein, the carrier 11 is a printed circuit board in one example.

The LED dies 12 are disposed on the carrier 11 along a longitudinal direction of the carrier 11. Herein, the longitudinal direction is parallel to the direction of the length L). The invention does not intend to restrict the number, type and color light of the LED dies 12. The LED die 12 may be, for example, a side-lighting LED (side-LED) or a top-lighting LED (top-LED). The color of light outputted from the LED die 12 may be, for example, white, red, green, blue, yellow or any other color. The LED dies 12 may be bonded to the carrier 11 by way of wire bonding o flip chip bonding. In this example, the LED die 12 is wire-bonded to the carrier 11.

The reflecting element 13 has two reflecting portions 131 and 132, which are disposed on the carrier 11 along the longitudinal direction, wherein the LED dies 12 are disposed between the reflecting portions 131 and 132. Using the reflecting element 13 to reflect the light outputted from the LED dies 12 can increase the light availability and enhance the directivity of light.

The material of the reflecting element 13 may include a plastic or metal material or any other reflective material. The reflecting element 13 may be closed or non-closed. In this example, the reflecting element 13 is non-closed. In this embodiment, the reflecting portions 131 and 132 of the reflecting element 13 are disposed substantially in parallel. Of course, the aspect of the reflecting element 13 of FIG. 2 is only for the illustrative purpose. In fact, the reflecting element 13 may have many modifications. For example, the reflecting element 13 may include three or more than three reflecting portions disposed around the LED dies 12 with gaps formed between the three reflecting portions. Alternatively, the reflecting portions may be connected to one another. In addition, the reflecting element 13 may be connected to the carrier 11 by way of engaging, adhering, embedding or injection molding. In this example, the reflecting element 13 is adhered to the carrier 11.

The molding material 14 covers the LED dies 12 and contacts with the reflecting element 13. Herein, the reflecting element 13 serves as a stop wall of the molding material 14. In addition, one side 141 of the molding material 14 (i.e., the upper surface of the molding material 14) away from the carrier 11 is a plane, which may be leveled by a scraper to prevent the large thickness variations of the molding material 14, through which the LED dies 12 pass.

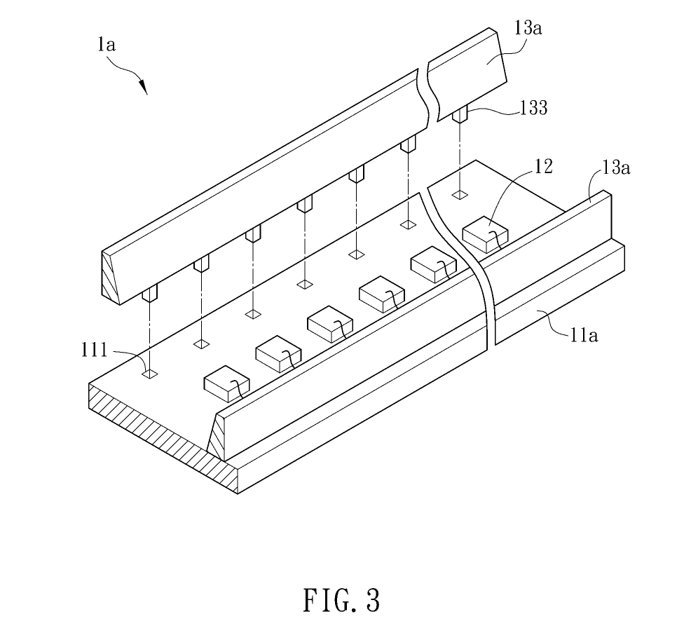

FIG. 3 is a schematic illustration showing a LED unit 1a before being covered by a molding material according to another aspect of this embodiment. In order to facilitate the positioning, a reflecting element 13a of the LED unit 1a and the carrier 11a are concave-convex matched. For example, the carrier 11a may have a concave portion, the reflecting element 13a has a convex portion. Alternatively, the carrier 11a may have a convex portion, and the reflecting element 13a has a concave portion. In this example, the carrier 11a has a concave portion 111, and the reflecting element 13a has the convex portion 133. The matching between the concave portion 111 and the convex portion 133 is advantageous to the aligned arrangement of the reflecting element 13a with the carrier 11a, and also advantageous to the firm connection between the reflecting element 13a and the carrier 11a.

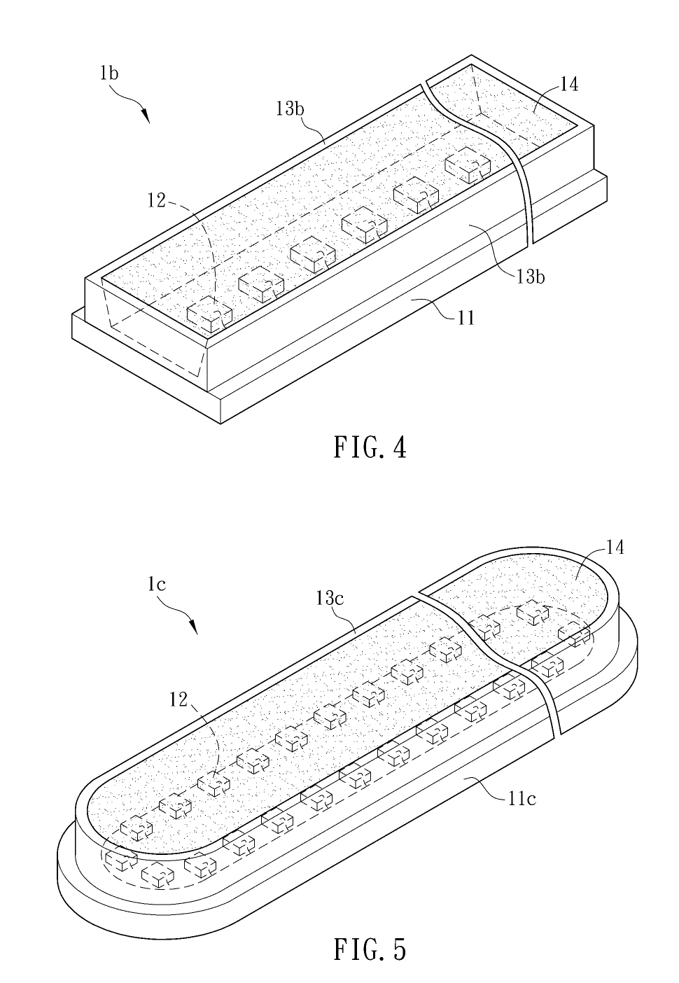

FIGS. 4 and 5 are schematic illustrations showing LED units 1b and 1c according to other aspects of FIG. 2. In these aspects, reflecting elements 13b and 13c of the LED units 1b and 1c are integrally formed, or reflecting portions thereof are connected together. The reflecting element 13b of FIG. 4 has a rectangular shape, and the reflecting element 13c of FIG. 5 has an elliptic shape. It is to be noted that the LED die 12 of the LED unit 1c may have different arrangements, such as an array-type or non-linear arrangement, depending on the product designs.

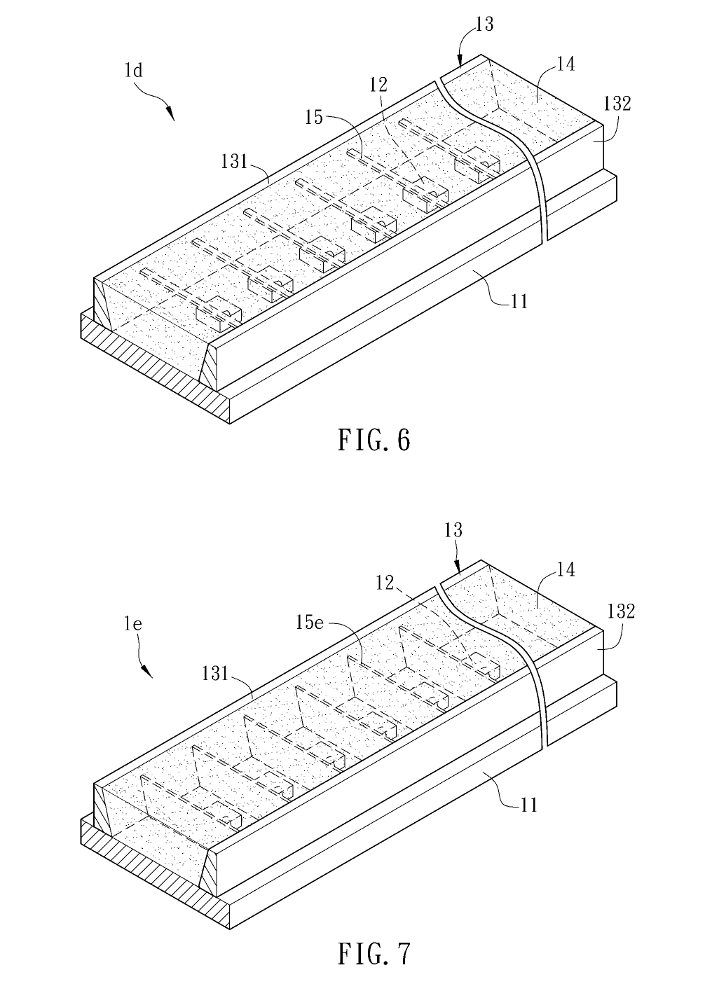

Referring to FIG. 6, a LED unit 1d according to another aspect of this embodiment may further include at least one supporting portion 15, which connects the reflecting portions 131 and 132. In this example, the supporting portion 15 has a rod-like structure and has two ends respectively connected to the reflecting portions 131 and 132. The supporting portion 15 may be connected to the reflecting portions 131 and 132 by way of engaging, adhering, bonding or integrally forming. The material of the supporting portion 15 may include, for example but without limitation to, a plastic, metal, light-permeable material, or any other material.

The provision of the supporting portion 15 can increase the structural strength of the reflecting element 13 to prevent the longitudinal reflecting element 13 from getting deformed under stresses during the curing process of the molding material 14. In addition, the supporting portion 15 can provide the separating effect to the overall structure of the molding material 14, so that the stresses caused by heating or cooling the molding material 14 can be decreased, the extent that the wires are twitched by the stresses can be decreased, and the product reliability can be enhanced. In addition, a height of the supporting portion 15 is smaller than a height of the reflecting element 13. Thus, the supporting portion 15 does not affect the circulation of the molding material 14, so that the molding material 14 is finally formed with a smooth surface.

FIG. 7 shows a LED unit 1e of another aspect. The main difference between the LED unit 1e and the LED unit 1d is that the LED unit 1e has a sheet-like supporting portion 15e made of a sapphire substrate (e.g., a waste LED substrate) or glass. In addition, the supporting portion 15e may have a highly reflective surface (e.g., a reflective sheet) for reflecting the light outputted from the LED die 12 to unify the directivity of light. Alternatively, the supporting portion 15e may also be made of a light-permeable material, such as frosted glass, to achieve the light-mixing effect. The supporting portion 15e is connected to the reflecting portions 131 and 132, and may be further connected to the carrier 11 to increase the overall structural strength of the reflecting element 13. In addition, the supporting portion 15e separates the overall structure of the molding material 14, and thus can decrease the heating/cooling stresses of the molding material 14, decrease the extent that the wires are twitched by the stresses, and thus enhance the product reliability.

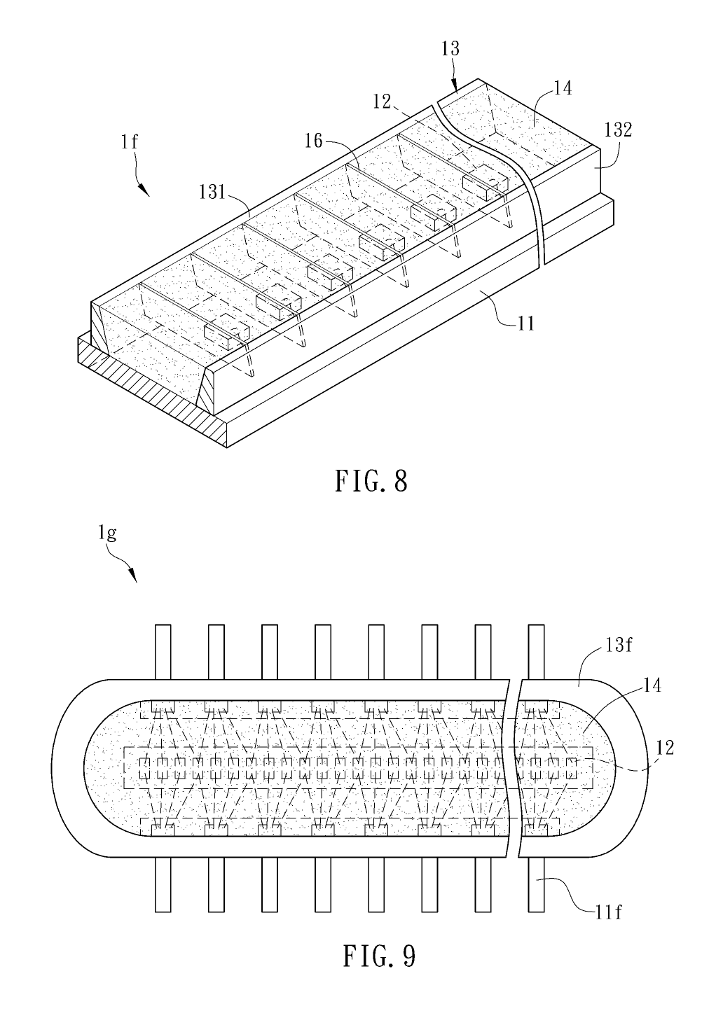

FIG. 8 is a schematic illustration showing a LED unit, which further includes a spacer. In order to decrease the accumulated stresses of the molding material 14 and the phenomenon that the wires are twitched by the stresses, this embodiment provides a LED unit if further including at least one spacer 16, which is disposed on the carrier 11, in the molding material 14 or on the reflecting element 13, and may be disposed between two neighboring LED dies 12. The spacer 16 may be a physical substance, a seam, a bubble or the like, wherein the physical substance may be made of the material similar to the material of the supporting portion. Herein, the spacer 16 is the seam in this example, and the spacers 16 are disposed between the LED dies 12. Of course, this does not intend to restrict the invention, and the spacer 16 may be removed from the position between two LED dies 12.

The seam may be formed by way of laser cutting or any other physical cutting method; while the bubble may be formed by way of laser engraving or any other method. The seam or bubble completely or partially cut the molding material 14 of the LED unit if into discontinuous portions, and may be formed at the position of the upper or lower half portion of the molding material 14 between the two LED dies 12 of the LED unit 1f. In this example, the seam is formed at the position of the upper half portion of the molding material 14 to partially cut the molding material 14 in order to decrease the accumulated stresses of the molding material 14, and decrease the stresses of twitching the wires.

In addition, the fluorescent particles of this invention may be disposed on the LED die, the molding material, the reflecting element, the carrier, or the surface of the supporting portion, or in the supporting portion or a combination thereof.

FIG. 9 shows another LED unit 1g according to the preferred embodiment of the invention. The main difference between the LED unit 1g and the LED unit 1 resides in that a carrier 11f of the LED unit 1g is a lead frame. The LED die 12 is disposed on the carrier 11f and wire-bonded to the signal pins of the carrier 11f. The reflecting element 13f includes two reflecting portions, which are connected together and disposed on the carrier 11f along the longitudinal direction. The LED die 12 is disposed between the reflecting portions, and the carrier 11f surrounds the LED dies 12. The molding material 14 covers the LED dies 12 and contacting with the reflecting element 13f.

To sum up, the same molding material covers a plurality of LED dies in the LED unit of the invention, so that the molding material corresponding to each LED die has the substantially constant thickness. The molding material contains the mixed fluorescent particles, and the concentration of the fluorescent particles corresponding to each LED die is also substantially constant, so that the uniform luminance can be obtained. In addition, the LED dies of the invention are disposed along the longitudinal direction of the carrier, and reflecting elements, for reflecting the light outputted from the LED die, are disposed on two sides of the LED die, so that the higher light availability is obtained.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light emitting diode (LED) unit, comprising:
a carrier having a length-width ratio greater than or equal to 5;
a plurality of LED dies disposed on the carrier along a longitudinal direction of the carrier;
a reflecting element having two reflecting portions disposed on the carrier along the longitudinal direction, wherein the LED dies are disposed between the reflecting portions; and
a molding material covering the LED dies and contacting with the reflecting element.

2. The LED unit according to claim 1, wherein the carrier is a circuit board or a lead frame.

3. The LED unit according to claim 1, wherein the reflecting element is closed or non-closed.

4. The LED unit according to claim 1, wherein the reflecting element is integrally formed.

5. The LED unit according to claim 1, wherein the reflecting element is connected to the carrier by way of engaging, adhering, embedding or injection molding.

6. The LED unit according to claim 5, wherein the reflecting element and the carrier are concave-convex matched.

7. The LED unit according to claim 1, further comprising:
at least one supporting portion connected to the reflecting portions.

8. The LED unit according to claim 7, wherein a height of the supporting portion is smaller than a height of the reflecting element.

9. The LED unit according to claim 1, wherein the reflecting portions are disposed substantially in parallel.

10. The LED unit according to claim 1, wherein a material of the reflecting element comprises a plastic material or a metal material.

11. The LED unit according to claim 1, wherein one side of the molding material away from the carrier is a plane.

12. The LED unit according to claim 1, wherein the molding material continuously covers the LED dies.

13. The LED unit according to claim 1, further comprising:
at least one spacer disposed on the carrier, the molding material or the reflecting element.

14. The LED unit according to claim 13, wherein at least a portion of the spacer is disposed between neighboring two of the LED dies.
